(19) United States
(12) Patent Application Publication
(10) Pub. No.: US 2013/0299766 A1
(43) Pub. Date: Nov. 14, 2013

(54) VARIABLE RESISTANCE MEMORY DEVICE AND METHODS OF FORMING THE SAME

(71) Applicants: Doo-Hwan Park, Gyeonggi-do (KR); Daehwan Kang, Seoul (KR); Hideki Horii, Seoul (KR)

(72) Inventors: Doo-Hwan Park, Gyeonggi-do (KR); Daehwan Kang, Seoul (KR); Hideki Horii, Seoul (KR)

(21) Appl. No.: 13/937,511

(22) Filed: Jul. 9, 2013

Related U.S. Application Data
(63) Continuation of application No. 12/836,134, filed on Jul. 14, 2010, now abandoned.

(30) Foreign Application Priority Data
Dec. 29, 2009 (KR) 10-2009-0133094

(51) Int. Cl. H01L 45/00

(52) U.S. Cl. CPC H01L 45/12
USPC 257/2

(57) ABSTRACT

A semiconductor memory device includes a first electrode and a second electrode, a variable resistance material pattern including a first element disposed between the first and second electrode, and a first spacer including the first element, the first spacer disposed adjacent to the variable resistance material pattern.

### CROSS-REFERENCE TO RELATED APPLICATIONS

This application is a Continuation of U.S. application Ser. No. 12/836,134 filed on Jul. 14, 2010, which claims priority under 35 U.S.C. 119 to Korean Patent Application No. 10-2009-0133094, filed on Dec. 29, 2009, the disclosures of which are incorporated by reference herein in their entireties.

### BACKGROUND

1. Technical Field

The present inventive concept relates to semiconductor memory devices and methods of forming the same, and more particularly, to variable resistance memory devices and methods of forming the same.

2. Discussion of Related Art

Variable resistance memory device types include, for example, ferroelectric random access memory (FRAM), magnetic random access memory (MRAM) and phase-change random access memory (PRAM). Materials used for data storage in such nonvolatile semiconductor memory devices have different states for different data, and maintain the data even when a supply of a current or a voltage is interrupted. The PRAM uses a variable resistance material pattern for data storage.

When the variable resistance material pattern contacts an oxide layer, oxygen from the oxide layer may diffuse into the variable resistance material pattern. This diffusion of oxygen may deteriorate the operation of the PRAM. For example, the diffusion may affect the resistance distribution of a memory cell in the PRAM, and may increase a set resistance of the memory cell in the PRAM.

### SUMMARY

According to an exemplary embodiment of the inventive concept, a spacer is disposed on the variable resistance material pattern to prevent oxygen diffusing from an oxide layer into the variable resistance material pattern.

According to an exemplary embodiment of the inventive concept, a spacer is disposed on the variable resistance material pattern to supply germanium (Ge) into the variable resistance material pattern.

According to an exemplary embodiment, a semiconductor device comprises a first electrode and a second electrode, a variable resistance material pattern comprising a first element disposed between the first and second electrode, and a first spacer comprising the first element, the first spacer disposed between the second electrode and the variable resistance material pattern.

The first element may comprise Ge.

The first spacer may comprise DaMbGe (100-a-b), where a=0-70, b=0-20, D=C, N or O, and M=Al, Ga, In, Ti, Cr, Mn, Fe, Co, Ni, Zr, Mo, Ru, Pd, Hf, Ta, Ir or Pt.

The variable resistance material pattern may comprise at least one of DGeSbTe where D comprises C, N, Si, Bi, In, As or Sc, DGeBiTe where D comprises C, N, Si, In, As or Se, DsbTe where D comprises As, Sn, SuIn, W, Mo or Cr, DSbSe where D comprises N, P, As, Sb, Bi, O, S, Te or Po, or DSB where D comprises Ge, Ga, In, Ge, Ga or In.

The semiconductor device may further comprise a second spacer comprising the first element, the second spacer disposed adjacent to the variable resistance material pattern and opposite the first spacer.

The first and second spacers can directly contact the variable resistance material pattern.

The variable resistance material pattern may comprise a substantially U-shaped cross section.

The semiconductor device may further comprise a second spacer comprising the first element, the second spacer disposed adjacent to the variable resistance material pattern and perpendicular to the first spacer.

The first and second spacers may directly contact the variable resistance material pattern.

The semiconductor device may further comprise an inner insulating layer disposed between the variable resistance material pattern and the second electrode.

The inner insulating layer may comprise a first layer and a second layer disposed on the first layer, the second layer having a different O₂ concentration from the first layer.

The inner insulating layer may comprise at least one of borosilicate glass (BSG), phosphosilicate glass (PSG), borophosphosilicate glass (BPSG), plasma enhanced tetra ethyl ortho silicate (PE-TEOS) or a high density plasma (HDP) layer.

The first electrode can be electrically connected to a word line and the second electrode can be electrically connected to a bit line.

The first electrode can be disposed on a substrate.

The first spacer may directly contact the variable resistance material pattern.

According to an exemplary embodiment, a semiconductor device comprises an interlayer insulating layer disposed between a first electrode and a second electrode, the first electrode disposed on a substrate, an opening formed through the interlayer insulating layer, the opening exposing the first electrode, a variable resistance material pattern comprising a first element, the variable resistance material pattern disposed within the opening and contacting the first electrode, and a first spacer comprising the first element, the first spacer disposed between the interlayer insulating layer and the variable resistance material pattern.

The first element may comprise Ge.

The first spacer may comprise DaMbGe, where 0.2, D comprises C, N or O, and M comprises Al, Ga, In, Ti, Cr, Mn, Fe, Co, Ni, Zr, Mo, Ru, Pd, Hf, Ta, Jr or Pt.

The variable resistance material pattern may comprise at least one of DGeSbTe where D comprises C, N, Si, Bi, In, As or Se, DGeBiTe where D comprises C, N, Si, In, As or Se, DsbTe where D comprises As, Sn, SnIn, W, Mo or Cr, DSbSe where D comprises N, P, As, Sb, Bi, O, S, Te or Po, or DSB where D comprises Ge, Ga, In, Ge, Ga or In.

The semiconductor device may further comprise a second spacer comprising the first element, the second spacer disposed adjacent to the variable resistance material pattern and opposite the first spacer.

The opening may comprise a side wall and a bottom wall.

The first spacer can be disposed on the side wall of the opening.

The variable resistance material pattern may comprise a sidewall and a bottom wall.

The side wall of the variable resistance material pattern can be disposed on the first spacer and the bottom wall of the variable resistance material pattern can be disposed on the first electrode.

The semiconductor device may further comprise a second spacer having the first element, the second spacer comprising a side wall and a bottom wall.

The side wall of the second spacer can be disposed on the side wall of the variable resistance material pattern and the bottom wall of the second spacer can be disposed on the bottom wall of the variable resistance material pattern.

The semiconductor device may further comprise a second spacer disposed on the variable resistance material pattern and perpendicular to the first spacer.

The semiconductor device may further comprise an inner insulating layer disposed between the bottom wall of the variable resistance material pattern and the second electrode.

The inner insulating layer may comprise a first layer and a second layer disposed on the first layer, the second layer having a different O₂ concentration from the first layer.

Sides of the opening may be inclined with respect to the first electrode.

According to an exemplary embodiment, a method of forming a semiconductor device comprises forming a first electrode in a first interlayer insulating layer disposed on a substrate, forming a second interlayer insulating layer on the first interlayer insulating layer and on the first electrode, forming an opening through the second interlayer insulating layer, forming a first spacer comprising a first element on a side wall of the opening, forming a variable resistance material pattern comprising the first element on the first electrode and the first spacer, forming a second spacer comprising the first element on the variable resistance material pattern, and forming a second electrode on the variable resistance material pattern.

The first element may comprise Ge.

The first and second spacers may each comprise DaMbGe, where 0≦-a≦0.7, D comprises C, N or O, and M comprises Al, Ga, In, Ti, Cr, Mn, Fe, Co, Ni, Zr, Mo, Ru, Pd, Hf, Ta, Ir or Pt.

The variable resistance material pattern may comprise at least one of DGeSbTe where D comprises C, N, Si, Bi, In, As or Se, DGeBiTe where D comprises C, N, Si, In, As or Se, DsbTe where D comprises As, Sn, SnIn, W, Mo or Cr, DSbSe where D comprises N, P, As, Sb, Bi, O, S, Te or Po, or DSB where D comprises Ge, Ga, In, Ge, Ga or In.

The second spacer may be conformally formed on the variable resistance material pattern.

The method may further comprise forming an inner insulating layer on the second spacer.

The inner insulating layer and the second insulating layer may each comprise at least one of borosilicate glass (BSG), phosphosilicate glass (PSG), borophosphosilicate glass (BPSG), plasma enhanced tetra ethyl ortho silicate (PE-TEOS) or a high density plasma (HDP) layer

The method may further comprise forming a buffer layer on the variable resistance material pattern.

The method may further comprise forming a metal contact through a third insulating layer disposed on the second electrode, the metal contact connecting the second electrode and a bit line disposed on the third insulating layer.

Forming an opening may comprise anisotropically etching the second interlayer insulating layer.

### BRIEF DESCRIPTION OF THE DRAWINGS

Exemplary embodiments of the present invention can be understood in more detail from the following descriptions taken in conjunction with the accompanying drawings, in which:

FIG. 1 is a circuit view of a cell array of a variable resistance memory device according to an exemplary embodiment of the inventive concept;

FIG. 2 is a plan view of a variable resistance memory device according to an exemplary embodiment of the inventive concept;

FIG. 3 is a cross sectional view of a cell of a variable resistance memory device taken along the line I-I′ in FIG. 2 according to an exemplary embodiment of the inventive concept;

FIG. 4 is a cross sectional view of a cell of a variable resistance memory device taken along the line I-I′ in FIG. 2 according to an exemplary embodiment of the inventive concept;

FIG. 5A through FIG. 5F show a method of forming a cell of a variable resistance memory device according to an exemplary embodiment of the inventive concept;

FIG. 6 is a flowchart describing a method of forming a cell of a variable resistance memory device according an exemplary embodiment of the inventive concept;

FIG. 7A through FIG. 7D show different types of lower electrodes included in a cell of a variable resistance memory device according to exemplary embodiments of the inventive concept;

FIG. 8 is a plan view of a variable resistance memory device according to an exemplary embodiment of the inventive concept;

FIG. 9 is a cross-sectional view of a cell taken along the line I-I′ in FIG. 8 according to an exemplary embodiment of the inventive concept;

FIG. 10 is a cross-sectional view of a cell of a variable resistance memory device according to an exemplary embodiment of the inventive concept;

FIG. 11 is a cross-sectional view of a cell of a variable resistance memory device according to an exemplary embodiment of the inventive concept;

FIG. 12 is a cross-sectional view of a cell of a variable resistance memory device according to an exemplary embodiment of the inventive concept;

FIG. 13 is a plan view of a variable resistance memory device according to an exemplary embodiment of the inventive concept;

FIG. 14 is a cross-sectional view of a cell taken along the line I-I′ in FIG. 13 according to an exemplary embodiment of the inventive concept;

FIGS. 15-20 show a method of forming a cell of a variable resistance memory device according to an exemplary embodiment of the inventive concept;

FIG. 21 is a plan view of a variable resistance memory device according to an exemplary embodiment of the inventive concept;

FIG. 22 is a cross-sectional view of a cell taken along the line I-I′ in FIG. 21 according to an exemplary embodiment of the inventive concept;

FIG. 23 is a graph showing an endurance of a variable resistance memory device when a Ge spacer is used in the device (case b) according to an exemplary embodiment of the inventive concept, and when a Ge containing spacer is not used in the device (case a);

FIG. 24 is a graph showing data retention when a Ge spacer is not used in a variable resistance memory device;

FIG. 25 is a graph showing data retention when a Ge spacer is used in a memory device according to an exemplary embodiment of the inventive concept;

FIG. 26 is a graph showing an endurance of a variable resistance memory device when a Ge₁Te₁₋ₓ spacer is used in the device (case b) according to an exemplary embodiment of the inventive concept, and when a Ge containing spacer is not used in the device (case a);

FIG. 27 is a graph showing data retention when a Ge₁Te₁₋ₓ spacer is not used in a variable resistance memory device;

FIG. 28 is a graph showing data retention when a Ge₁Te₁₋ₓ spacer is used in a memory device according to an exemplary embodiment of the inventive concept;

FIG. 29 is a table showing reset current, retention time, and endurance of a variable resistance memory device according to an exemplary embodiment of the inventive concept as compared to a variable resistance memory device that does not have a Ge containing spacer on the variable resistance material pattern; and

FIG. 30 is a block diagram of a memory system in which a variable resistance memory device according to an exemplary embodiment of the inventive concept may be implemented.

### DETAILED DESCRIPTION OF THE EMBODIMENTS

Exemplary embodiments of the inventive concept will now be described more fully with reference to the accompanying drawings. The inventive concept may, however, be embodied in many different forms and should not be construed as limited to only the exemplary embodiments set forth herein.

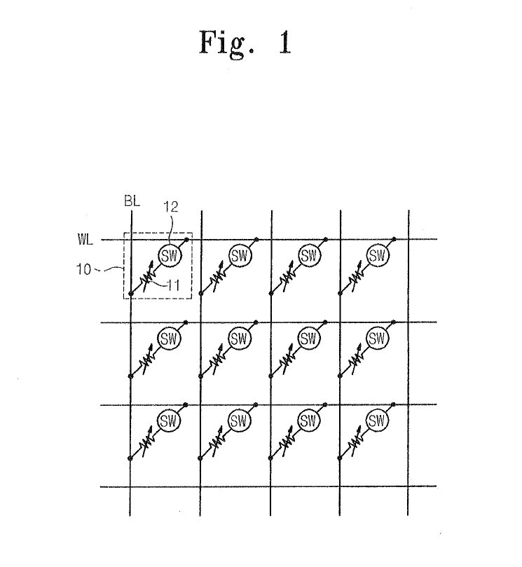

FIG. 1 is a circuit view of a cell array of a variable resistance memory device according to an exemplary embodiment of the inventive concept.

Referring to FIG. 1, a plurality of memory cells 10 are arranged in a matrix. Each of the memory cells 10 includes a variable resistance memory portion 11 and a selection circuit 12. The variable resistance memory portion 11 is disposed between the selection circuit 12 and a bit line BL and electrically connected to the selection circuit 12 and the bit line BL. The selection circuit 12 is disposed between the variable resistance memory portion 11 and a word line WL and electrically connected to the variable resistance memory portion 11 and the word line WE.

The variable resistance memory portion 11 may, for example, include a phase change material pattern. The phase change material pattern may include a chaleogenide material such as, for example, Ge₂Sb₂Te₅. A resistance of the phase change material pattern of the variable resistance memory portion 11 is changed when heat is applied thereto. The phase change material pattern may contact a lower electrode of the memory device. The lower electrode may function to provide the phase change material pattern with heat such that the temperature of the phase change material pattern can be controlled.

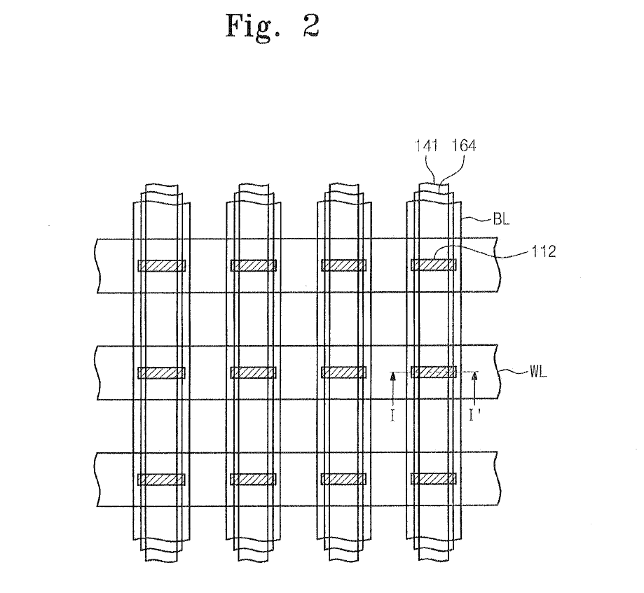

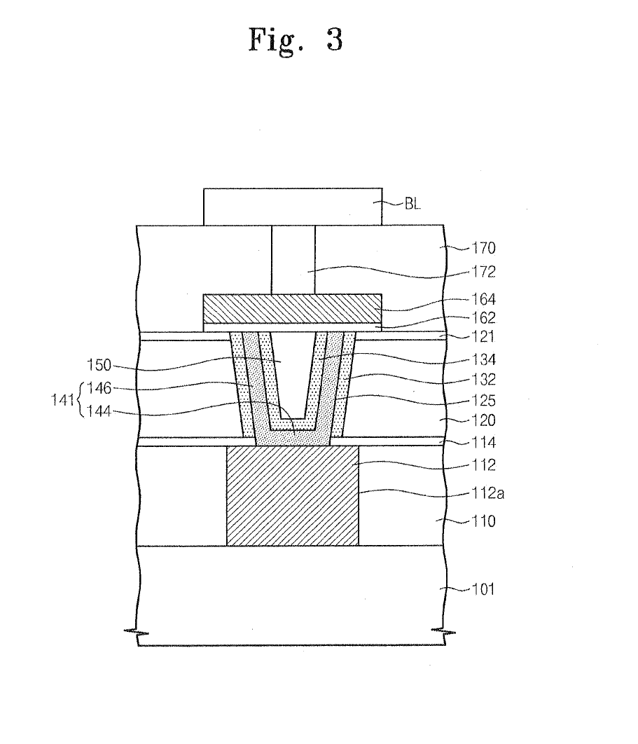

FIG. 2 is a plan view of a variable resistance memory device according to an exemplary embodiment of the inventive concept. FIG. 3 is a cross sectional view of a cell of a variable resistance memory device taken along the line I-I′ of FIG. 2 according to an exemplary embodiment of the inventive concept.

Referring to FIGS. 2 and 3, a first interlayer insulating layer 110 is disposed on a semiconductor substrate 101. An opening 112a is formed in the first insulating layer 110 to receive a lower electrode 112. The lower electrode 112 is disposed on the substrate 101. The semiconductor substrate 101 may include word lines WL extending in a first direction. The word lines may be doped with an impurity. The semiconductor substrate 101 may include a plurality of selection circuits, such as diodes or MOS transistors, and the plurality of selection circuits may be electrically connected to the lower electrode 112.

The first interlayer insulating layer 110 and the lower electrode 112 having, for example, a rectangular shape in a cross sectional view are disposed on the semiconductor substrate 101. Respective lower electrodes 112 are spaced apart with a predetermined distance from each other on the word lines. The lower electrode 112 may be arranged in the first direction or arranged in a second direction perpendicular to the first direction.

A second interlayer insulating layer 120 is disposed on the lower electrode 112, and a trench 125 exposing a portion of the top surface of the lower electrode 112 is formed in the second interlayer insulating layer 120. The trench 125 may extend in a first or second direction. The trench 125 may have a gradually narrowing profile as it approaches the lower electrode 112.

A variable resistance material pattern 141 includes two substantially vertically opposed wall members 146 and one bottom member 144 connecting the wall members 146 at bases thereof. A distance between the upper edges of the wall members 146 is greater than a width of the bottom member 144, and the wall members 146 are inclined with respect to the top surface of the lower electrode 112. As such, the variable resistance material pattern 141 disposed in the trench 125 has a substantially U-shaped cross section with an upper portion wider than a lower portion thereof. The variable resistance material pattern 141 may be formed of two or more compounds from a group including Te, Se, Ge, Sb, Bi, Pb, Sn, Ag, As, S, Si, P, O or C. For example, the variable resistance material pattern 141 comprises at least one of DGeSbTe where D=C, N, Si, Bi, In, As or Se, DGeBiTe where D=C, N, Si, In, As or Se, DSbTe where D=As, Sn, Snin, W, Mo or Cr, DSbSe where D=N, P, As, Sb, Bi, O, S, Te or Po, or DSb where D=Ge, Ga, In, Ge, Ga or In. As such, in an exemplary embodiment, the variable resistance material pattern 141 may comprise, for example, Ge₂Sb₂Te₅.

An inner spacer 134 can be disposed on inner surfaces of the variable resistance material pattern 141. The inner spacer 134 can be conformally disposed with a substantially consistent thickness on the inner surfaces of the variable resistance material pattern 141. The inner spacer 134 includes two substantially vertically opposed wall members and a bottom member connecting the wall members at bases thereof. An outer spacer 132 can be disposed on outer surfaces of the variable resistance material pattern 141. The outer spacer 132 can be disposed on sidewalls of the variable resistance material pattern 141. The inner and outer spacers 134 and 132 may comprise Ge or germanium-tellurium (GeTe). For example, the inner and outer spacers 134, 132 may comprise DₐM_{b}Ge, where 0≦a≦0.7, 0≦b≦0.2, D comprises C, N or O, and M comprises Al, Ga, In, Ti, Cr, Mn, Fe, Co, Ni, Zr, Mo, Ru, Pd, Hf, Ta, Ir or Pt.

According to an exemplary embodiment, the inner and outer spacers 134, 132 may comprise DₐM_{b}[GₓT_{y}]_{c} where 0≦a/(a+b+c)≦0.2, 0≦b/(a+b+c)≦0.1, and 0.3≦x/(x+y)≦0.7. D may comprise C, N or O. M may comprise Al, Ga, or In. G may comprise Ge. T may comprise Te. Gx may comprise Geₓ₁G′ₓ₂(0.8≦x1/(x1+x2)≦1). G′ may comprise Al, Ga, In, Si, Sn, As, Sb or Bi. T_{y} may comprise Te_{y1}Se_{y2} where 0.8≦y1/(y1+Fy2)≦1.

In an exemplary embodiment, an inner insulating layer 150 can be disposed on the inner spacer 134. The variable resistance material pattern 141 can be substantially conformally formed on the outer spacer 132 and the exposed portion of the lower electrode 112. For example, the wall member 146 can be disposed on the outer spacer 132, and the bottom member 144 can be disposed on the exposed portion of the lower electrode 112.

When the variable resistance material pattern 141 comprises Ge, the amount of Ge contained in the variable resistance material pattern 141 can be reduced when a variable resistance memory device such as, for example, a PRAM operates. This may result in the depletion of the Ge in the variable resistance material pattern 141. When the variable resistance material pattern 141 contains a reduced amount of Ge, the retention and endurance characteristics of the PRAM can be deteriorated. According to an exemplary embodiment of the inventive concept, the inner and outer spacers 134 and 132 can provide the variable resistance material pattern 141 with Ge. For example, Ge contained in the spacers 134 and 132 can be diffused into the variable resistance material pattern 141. As such, the variable resistance material pattern 141 can maintain a sufficient amount of Ge for an extended period of time by receiving Ge from the inner spacer 134 or outer spacer 132. In other words, the inner and outer spacers 134 and 132 function as a source for Ge needed in the variable resistance material pattern 141. Therefore, according to an exemplary embodiment of the inventive concept, retention and endurance characteristics of the PRAM can be improved.

The second interlayer insulating layer 120 may be, for example, a silicon oxide layer including borosilicate glass (BSG), phosphosilicate glass (PSG), borophosphosilicate glass (BPSG), plasma enhanced tetraethylorthosilicate (PE-TEOS) or high density plasma (HDP) layer. When the second interlayer insulating layer 120 or the inner insulating layer 150, respectively comprising oxide, directly contacts the variable resistance material pattern 141, the oxygen may diffuse into the variable resistance material pattern 141. When oxygen diffuses into the variable resistance material pattern 141, the operation of the PRAM can be deteriorated. For example, a set resistance of the PRAM may increase. According to an exemplary embodiment of the inventive concept, the inner and outer spacers 134 and 132 can also prevent the diffusion of oxygen from the insulating layers 120, 150 into the variable resistance material pattern 141.

A third interlayer insulating layer 170 is disposed on the second interlayer insulating layer 120. A first etch stopper 114 and a second etch stopper 121 can be respectively disposed between the first and second interlayer insulating layers 110, 120 and the second and third interlayer insulating layers 120, 170. An upper electrode 164 can be disposed on a top surface of the variable resistance material pattern 141. The upper electrode 164 may be disposed on the variable resistance material pattern 141, the inner spacer 134, the outer spacer 132, and the inner insulating layer 150. The upper electrode 164 may contact the wall member 146 while the lower electrode 112 may contact the bottom member 144 of the variable resistance material pattern 141. The upper electrode 164 may be disposed on two ends of the U-shape cross-section of the variable resistance material pattern 141.

In an exemplary embodiment, a buffer layer 162 may be disposed between the upper electrode 164 and the variable resistance material pattern 141. The buffer layer 162 prevents material from moving or being transferred between the variable resistance material pattern 141 and the upper electrode 164. The upper electrode 164 may have a plate shape substantially corresponding to the shape of the lower electrode 112 or may have a line shape perpendicular to the underlying word line WL. The upper electrode 164 may be connected to a bit line BL through a metal contact 172.

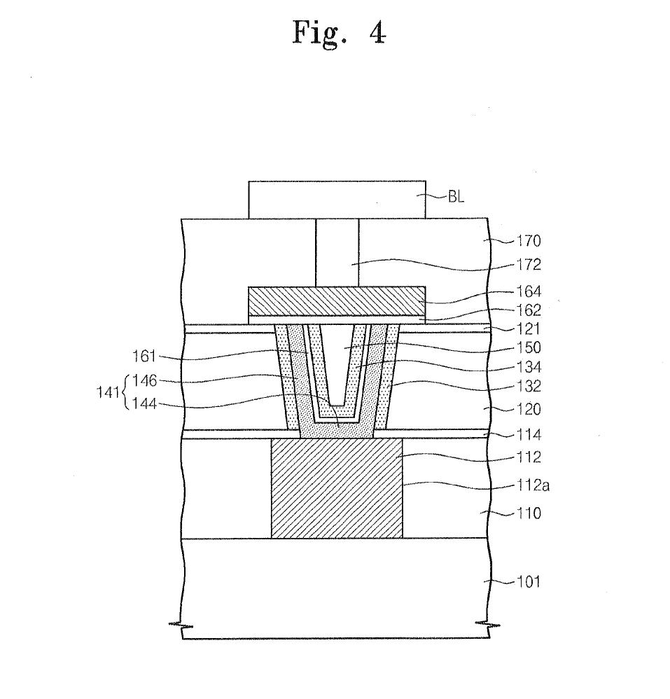

Referring to FIG. 4, a barrier layer 161 can be disposed between the inner spacer 134 and the variable resistance material pattern 141. The barrier layer 161 may comprise Ti, Ta, Mo, Hf, Zr, Cr, W, Nb, or V. The barrier layer 161 may block the movement of oxygen from the insulating layer 150 to the variable resistance material pattern 141.

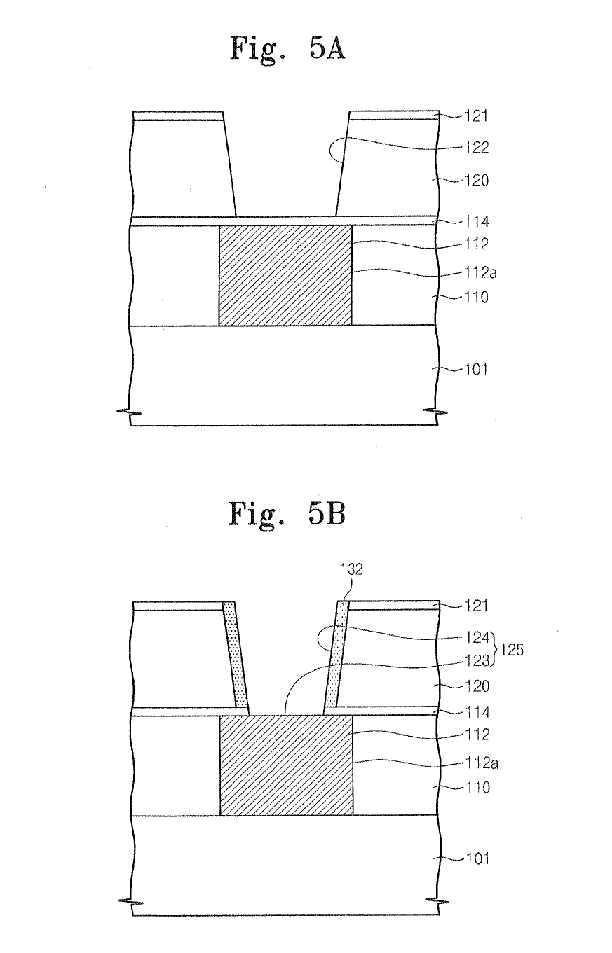

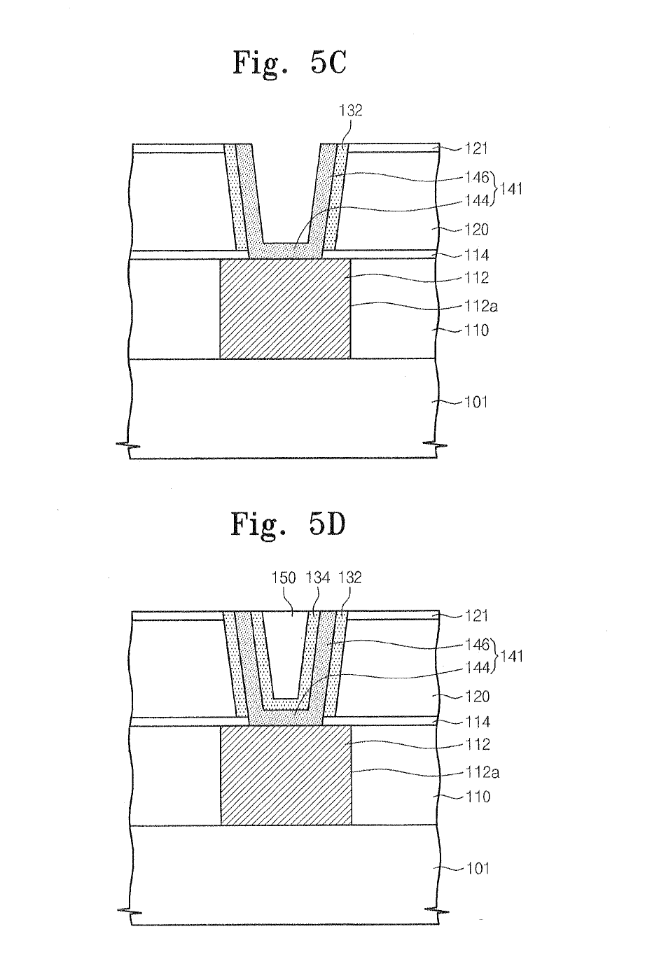

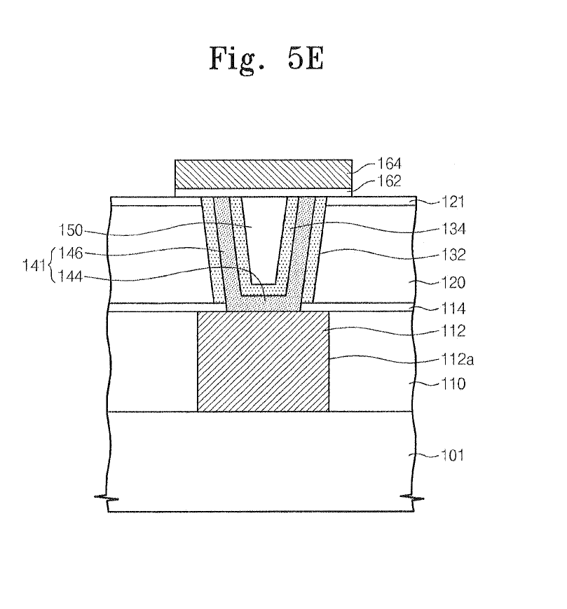

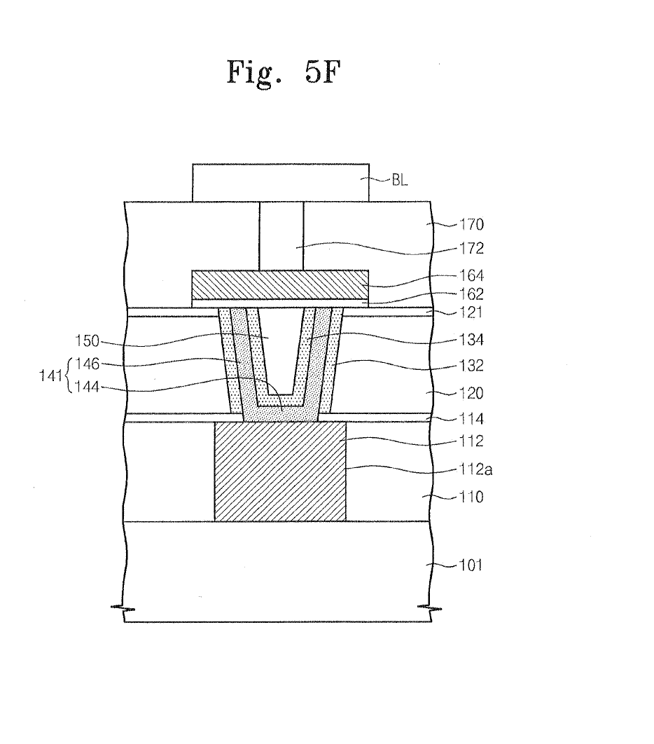

FIG. 5A through FIG. 5F show a method of forming a cell of a variable resistance memory device according to an exemplary embodiment of the inventive concept.

Referring to FIG. 5A, the first interlayer insulating layer 110 is disposed on the substrate 101. The opening 112a for receiving the lower electrode 112 is formed in the first interlayer insulating layer 110. The opening 112a may be arranged in one direction, e.g., a direction parallel to a word line or a direction perpendicular to the word line. The opening 112a may be formed in various shapes depending on a shape of the lower electrode 112. A conductive layer for the lower electrode 112 is patterned to form the lower electrode 112. The lower electrode 112 may comprise, for example, Ti, TiSix, TiN, TION, TiW, TiAIN, TiAION, TiSIN, TiBN, W, WSix, WN, WON, WSiN, WBN, WCN, Ta, TaSix, TaN, TaON, MAIN, TaSIN, TaCN, Mo, MoN, MoSiN, MoAIN, NbN, ZrAIN, Ru, CoSix, NiSix, conductive carbon group, Cu or a combination thereof.

A protection layer or the first etch stopper 114 may be formed on the lower electrode 110. For example, the first etch stopper 114 may be formed of SiN or SiON. When forming a preliminary trench 122 for forming the variable resistance material pattern 141, the first etch stopper 114 can protect the lower electrode 112.

The second interlayer insulating layer 120 is formed on the first interlayer insulating layer 110 and the lower electrode 112. The second interlayer insulating layer 120 is patterned to form the preliminary trench 122 for forming the variable resistance material pattern 141. The second interlayer insulating layer 120 may be, for example, a silicon oxide layer including borosilicate glass (BSG), phosphosilicate glass (PSG), borophosphosilicate glass (BPSG), plasma enhanced tetraethylorthosilicate (PE-TEOS) or high density plasma (HDP) layer. When forming the preliminary trench 122, the second interlayer insulating layer 120 may be anisotropically etched so that the preliminary trench 122 has a gradually narrowing profile as the preliminary trench 122 approaches the lower electrode 112. Thus, the preliminary trench 122 may be formed so that a width of the upper portion of the preliminary trench 122 is greater than a width of the lower portion of the preliminary trench 122. A width of the lower portion of the preliminary trench 122 may be less than a width of a major axis of the lower electrode 112.

Referring to FIG. 5B, the outer spacer 132 is disposed on a sidewall of the preliminary trench 122. A portion of the first etch stopper 114 is removed to expose a top surface of the lower electrode 112. The first etch stopper 114 can be patterned using the second etch stopper 121 and the outer spacer 132 as an etch mask. As such, a portion of the top surface of the lower electrode 112 may be exposed.

A trench 125 exposing the electrode 112 can be formed in the second interlayer insulating layer 120. The trench 125 includes a bottom side 123 exposing the electrode 112 and a wall side 124 extended from the bottom side 123.

Referring to FIG. 5C, the variable resistance material pattern 141 is conformally deposited along a surface of the outer spacer 132 and the exposed top surface of the lower electrode 112. The variable resistance material pattern 141 may be deposited to a thickness of about 1 nm to about 50 nm, for example, a thickness of about 3 nm to about 15 nm. A phase change material, such as a chalcogenide material layer, may be used as the variable resistance material pattern 141. The variable resistance material pattern 141 may be deposited using, for example, a physical vapor deposition (PVD) method or a chemical vapor deposition (CVD) method. The variable resistance material pattern 141 deposited in the trench 125 may have a uniform thickness according to an exemplary embodiment of the inventive concept.

Referring to FIG. 5D, the inner spacer 134 is deposited on the variable resistance material pattern 141. The inner insulating layer 150 is formed on the inner spacer 134 to fill the trench 125. The inner insulating layer 150 may comprise a material having a superior gap-filling characteristic, for example, high density plasma (HDP) oxide, plasma-enhanced tetraethylorthosilicate (PE-TEOS), borophosphosilicate glass (BPSG), undoped silicate glass (USG), flowable oxide (FOX) or hydrosilsesquioxane (FISQ), or spin on glass (SOG) including tonensilazene (TOSZ). A planarization process can be performed thereafter such that top surfaces of the inner insulating layer 150, the variable resistance material pattern 141, the outer spacer 132, and the inner spacer 134 may be coplanar.

Referring to FIG. 5E, the upper electrode 164 is formed on the variable resistance material pattern 141. A conductive layer can be patterned to form the upper electrode 164. The conductive layer may comprise, for example, Ti, TiSix, TiN, TION, TiW, TiAIN, TiAION, TiSiN, TiBN, W, WSix, WN, WON, WSiN, WBN, WCN, Ta, TaSix, TaN, TaON, TaAlN, TaSIN, TaCN, Mo, MoN, MoSiN, MoAIN, NBN, ArAIN, Ru, CoSix, NiSix, conductive carbon group, Cu or a combination thereof.

Before forming the upper electrode 164, the buffer layer 162 for preventing material from being diffused between the variable resistance material pattern 141 and the upper electrode 164 may be formed. The buffer layer 162 may include, for example, Ti, Ta, Mo, Hf, Zr, Cr, W, Nb, V, N, C, Al, B, P, O, or a combination thereof. For example, the buffer layer 162 may comprise TiN, TiW, TiCN, TiAIN, TiSiC, TaN, TaSiN, WN, MoN and/or CN.

Referring to FIG. 5F, the third interlayer insulating layer 170 is formed on the second interlayer insulating layer 120. The third interlayer insulating layer 170 is patterned to form a contact hole exposing the upper electrode 164. After the contact hole is filled with a conductive material to form the contact plug 172, the bit line BL is formed on the third interlayer insulating layer 170. The bit line BL may be perpendicular to a word line disposed thereunder.

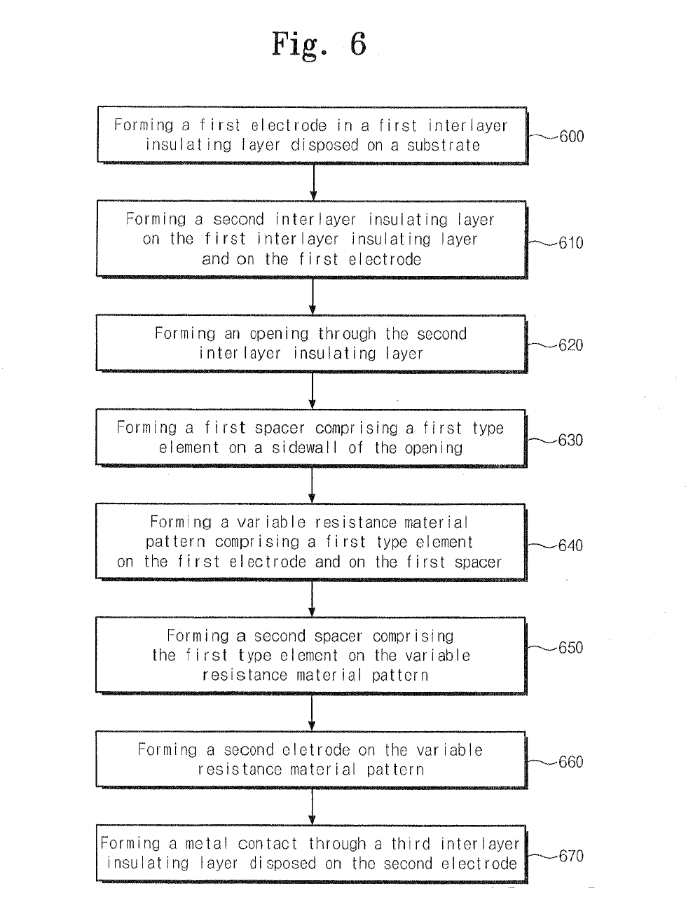

FIG. 6 is a flowchart showing a method of forming a cell of a variable resistance memory device according an exemplary embodiment of the inventive concept.

Referring to FIG. 6, in step 600, a first electrode is formed in a first interlayer insulating layer disposed on a substrate. In step 610, a second interlayer insulating layer is formed on the first interlayer insulating layer and on the first electrode. In step 620, an opening is formed through the second interlayer insulating layer. In an exemplary embodiment, the opening can be formed by anisotropically etching the second interlayer insulating layer. In step 630, a first spacer comprising a first type element is formed on a side wall of the opening. In step 640, a variable resistance material pattern comprising the first type element is formed on the first electrode and on the first spacer. In step 650, a second spacer comprising the first type element is formed on the variable resistance material pattern. In an exemplary embodiment, the second spacer can be conformally formed on the variable resistance material pattern. In an exemplary embodiment, an inner insulating layer can be formed on the second spacer. In step 660, a second electrode is formed on the variable resistance material pattern. In an exemplary embodiment, a buffer layer can be formed on the variable resistance material before forming the second electrode. In step 670, a third interlayer insulating layer is formed on the second interlayer insulating layer and a metal contact touching the second electrode is formed through the third interlayer insulating layer.

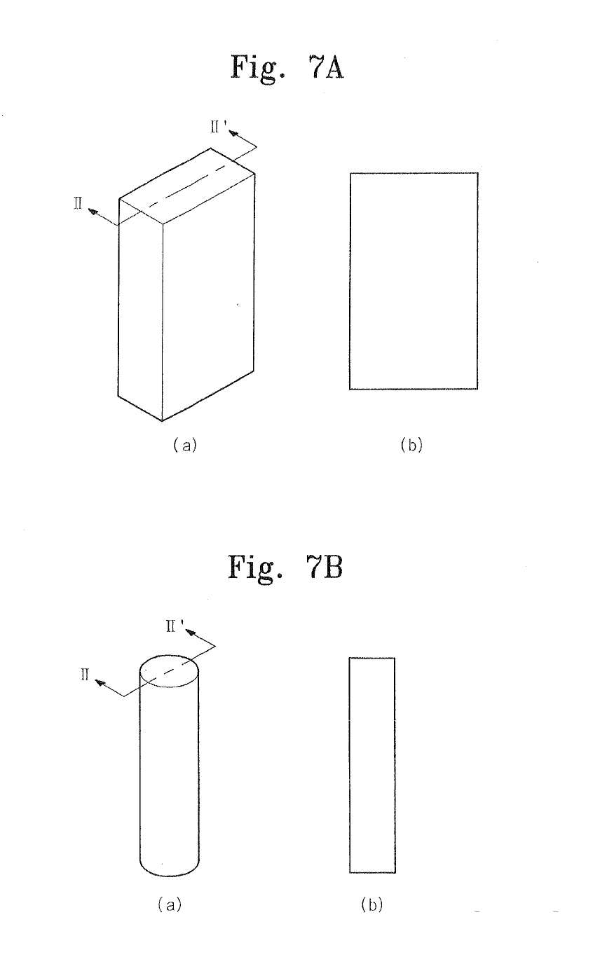

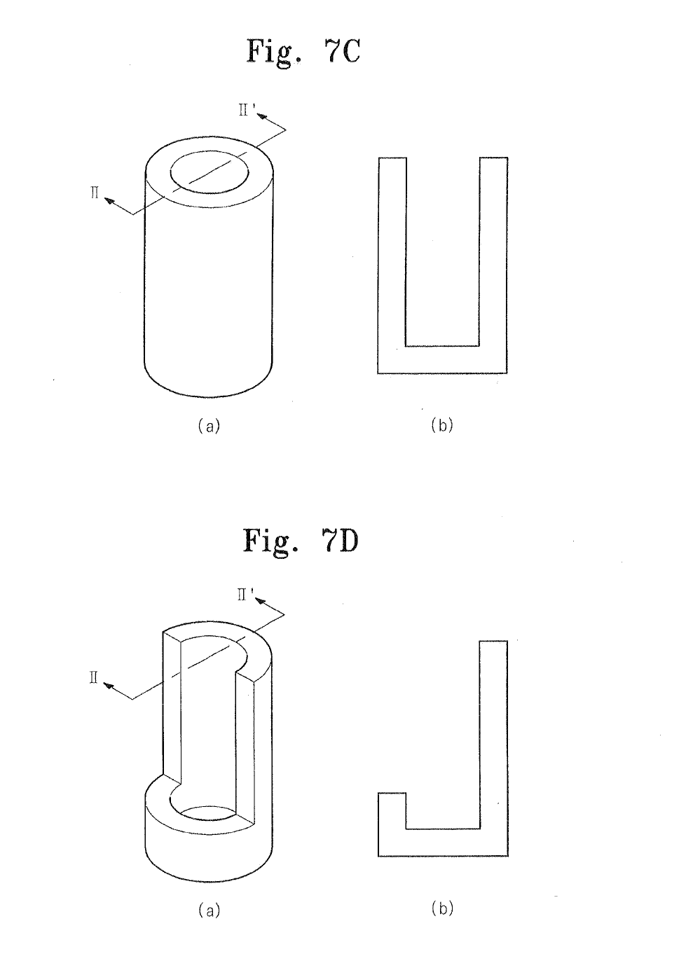

FIG. 7A through FIG. 7D show different types of lower electrodes included in a cell of a variable resistance memory device according to exemplary embodiments of the inventive concept. Referring to FIG. 7A through FIG. 7D, the lower electrode may have a variety cross-sectional shapes such as, for example, a rectangular shape, a square shape, a round shape, a ring shape or an arc shape such that the lower electrode can have a cylinder, tube, cutaway tube, or an elongated cubic shape from a perspective view. FIG. 7A(a) shows an elongated cubic shaped lower electrode, and FIG. 7A(b) is a cross-sectional view of the lower electrode taken along the line II-IF in FIG. 7A(a). FIG. 7B(a) shows an cylinder shaped lower electrode, and FIG. 7B(b) is a cross-sectional view of the lower electrode taken along line II-II′ in FIG. 7B(a). FIG. 7C(a) shows a tube shaped lower electrode, and FIG. 7C(b) is a cross-sectional view of the lower electrode taken along line II-II′ in FIG. 7C(a). FIG. 7D(a) shows a cutaway tube shaped lower electrode, and FIG. 7D(b) is a cross-sectional view of the lower electrode taken along line II-IF in FIG. 7D(a).

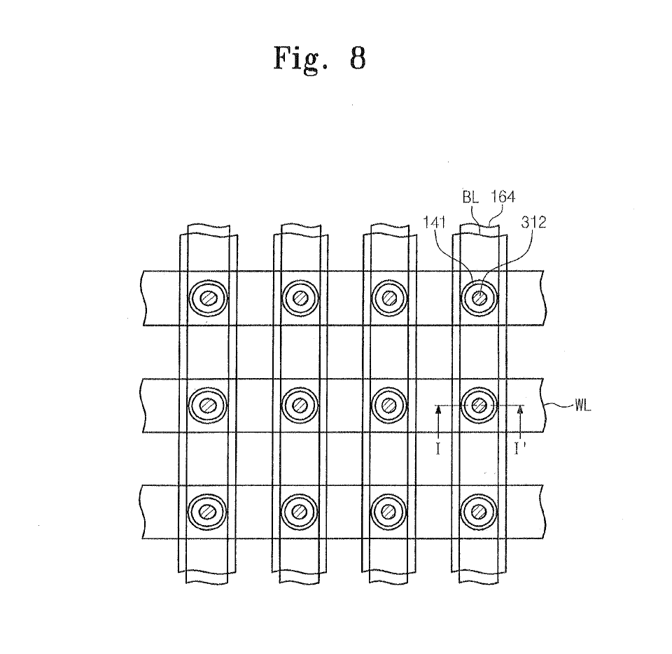

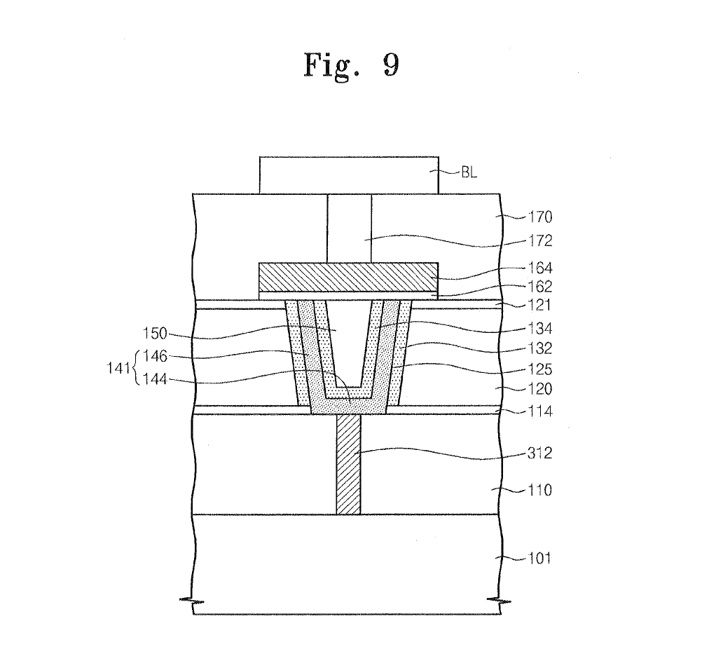

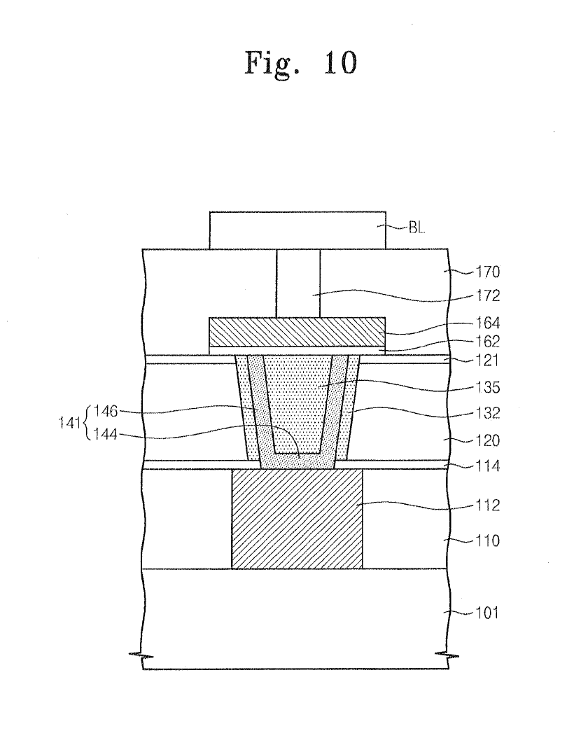

FIG. 8 is a plan view of a variable resistance memory device according to an exemplary embodiment of the inventive concept. FIG. 9 is a cross-sectional view of a cell in a variable resistance memory device according to an exemplary embodiment of the inventive concept. Referring to FIG. 9, the cell structure is substantially similar to the cell structure of FIG. 3, except for the shape of a lower electrode 312. For example, in FIG. 3, an elongated cubic type lower electrode is formed, and in FIG. 9, a cylinder type lower electrode 312 is formed.

FIG. 10 is a cross-sectional view of a cell in a variable resistance memory device according to an exemplary embodiment of the inventive concept. Referring to FIG. 10, the cell structure is substantially similar to the cell structure in FIG. 3, except for a second spacer 135 that occupies the opening formed by the wall members 146 and the bottom member 144 such that the inner insulating layer 150 shown in FIG. 3 is omitted.

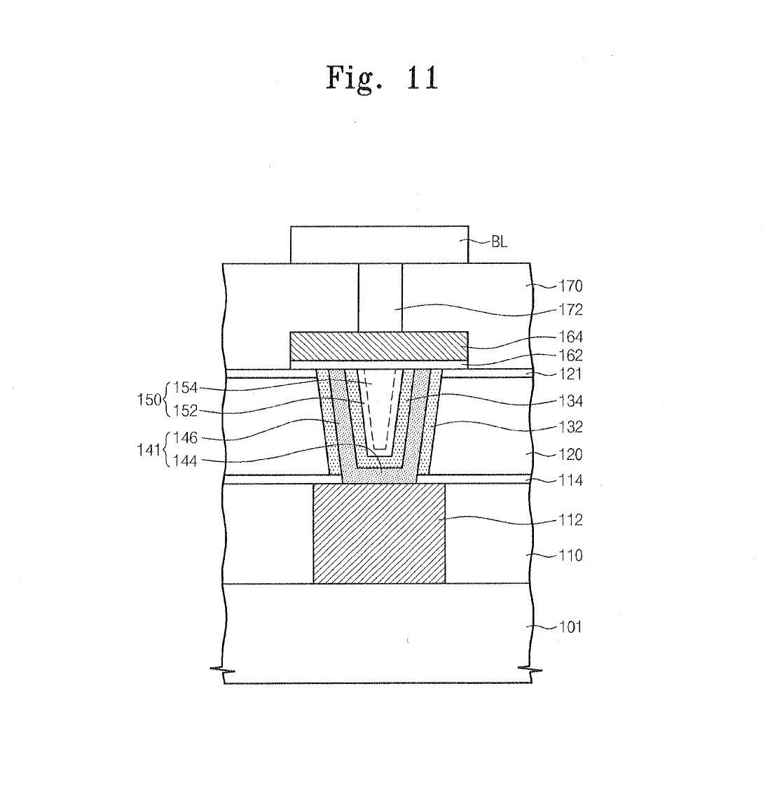

FIG. 11 is a cross sectional view of a variable resistance memory device according to an exemplary embodiment of the inventive concept. Referring to FIG. 11, the cell structure is substantially similar to the cell structure in FIG. 3 except the inner insulating layer 150 includes a low O₂ concentration layer 152 and a high O₂ concentration layer 154. The low O₂ concentration layer 152 is disposed on the second spacer 134, and the high O₂ concentration layer 154 is disposed on the low O₂ concentration layer 152. Accordingly, less oxygen is disposed near the variable resistance material pattern 141 such that the probability of the oxygen diffusing into the variable resistance material pattern 141 can be further lowered. According to an exemplary embodiment, the low O₂ concentration layer 152 can be formed by a USG process using oxygen gas or N₂O gas, and the high O₂ concentration layer 154 can be formed by a USG process using an ozone gas.

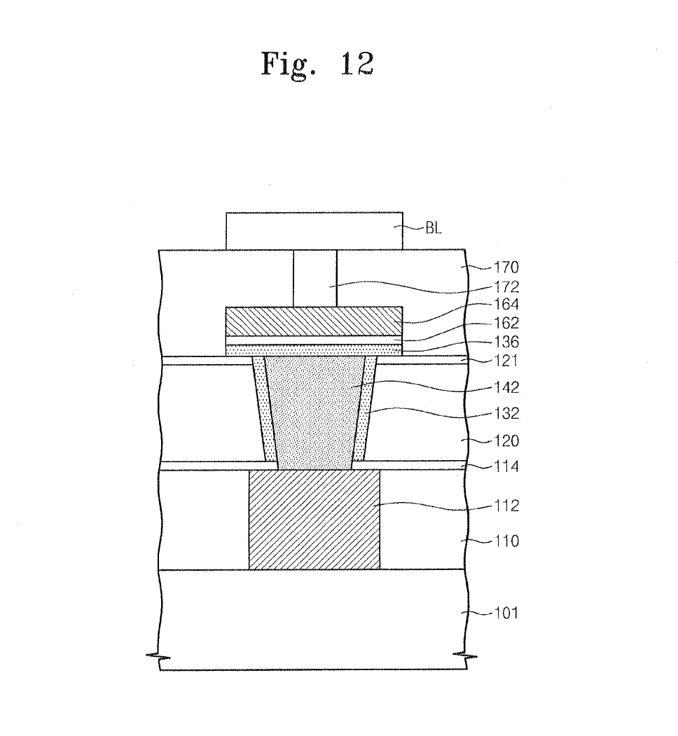

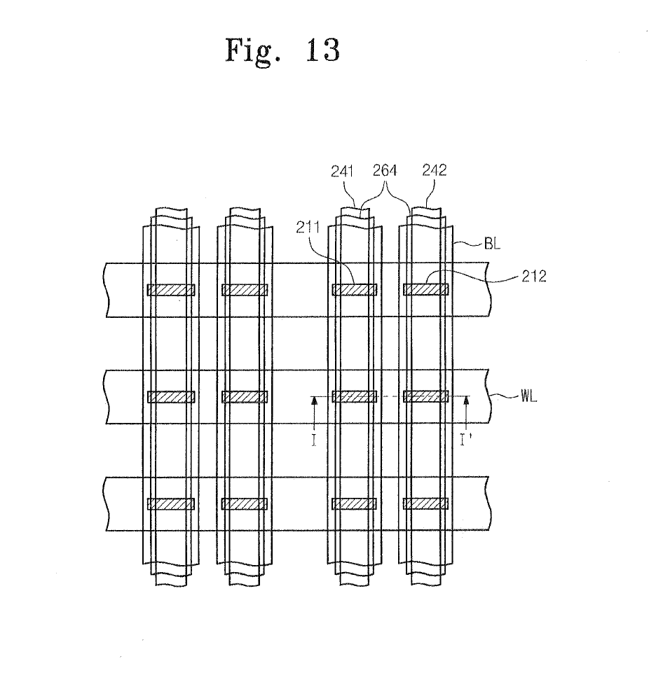

FIG. 12 is a cross-sectional view of a cell in a variable resistance memory device according to an exemplary embodiment of the inventive concept. Referring to FIG. 12, the cell structure is substantially similar to the cell structure in FIG. 3 except that the first spacer 132 is formed along sidewalls of the trench 125, and a second spacer 136 is disposed on the top surface of the first spacer 132 and the variable resistance material pattern 142. In addition, the variable resistance material pattern 142 fills the trench 125, and the second spacer 136 is disposed under the buffer layer 162. As such, the variable resistance material pattern 142 is disposed on and contacts the first and second spacers 132 and 136. For example, the first spacer 132 can be disposed on sidewalls of the variable resistance material pattern 142, and the second spacer 136 can be disposed on the top surface of the variable resistance material pattern 142.

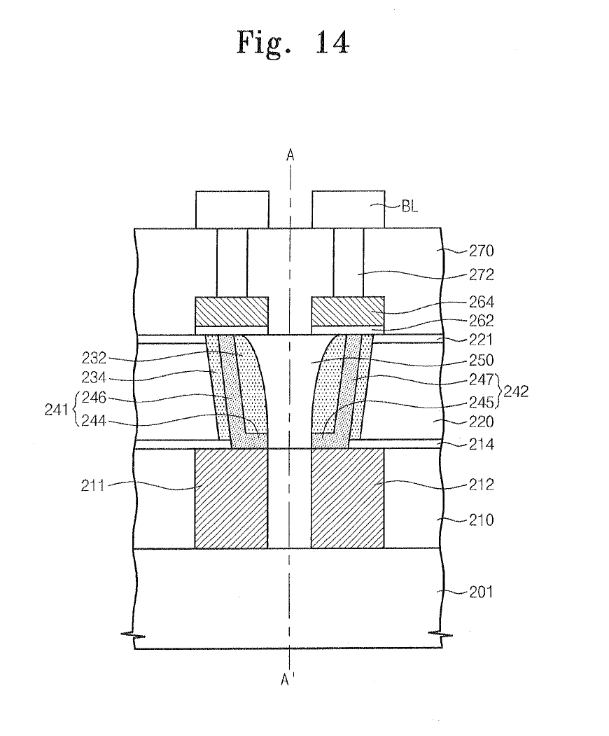

FIG. 13 is a plan view of a variable resistance memory device according to an exemplary embodiment of the inventive concept. FIG. 14 shows a cell in a variable resistance memory device according to an exemplary embodiment of the inventive concept. Referring to FIGS. 13 and 14, a pair of memory cells are disposed next to each other. In an exemplary embodiment, the memory cell on the left and the memory cell on the right can have a structure substantially symmetrical with respect to line A-A′. In an exemplary embodiment, a variable resistance material pattern 241 comprises a bottom member 244 and a wall member 246. The bottom member 244 and the wall member 246 are connected such that the variable resistance material pattern 241 has a substantially L-shape where the wall member 246 is inclined with respect to a major axis of substrate 201.

An inside spacer 234 and outside spacer 232 may comprise Ge. The inside spacer 234 is disposed on the inner surface of the L-shaped variable resistance material pattern 241. The outside spacer 232 is disposed on the outer surface of the L-shaped variable resistance material pattern 241. As such, the outside spacer 232 is disposed between a second interlayer insulating layer 220 and the L-shaped variable resistance material pattern 241. The variable resistance material pattern 242 facing the variable resistance material pattern 241 has substantially the same mirror image of the variable resistance material pattern 241. As such, the variable resistance material pattern 242 includes a wall member 247 and a bottom member 245. An end of the wall member 247 is connected to an end of the bottom member 245.

An insulating layer 250 is disposed between the respective inside spacers 234 and between the respective variable resistance material patterns 241 and 242. An insulating layer can be disposed between lower electrodes 211 and 212. An upper electrode 264 can be disposed on the variable resistance material pattern 242. A buffer layer 262 can be disposed between the upper electrode 264 and the variable resistance material pattern 242. A third interlayer insulting layer 270 is disposed on the second interlayer insulating layer 220. A contact 272 electrically connecting the upper electrode 264 and a bit line BL is formed in the third interlayer insulating layer 270.

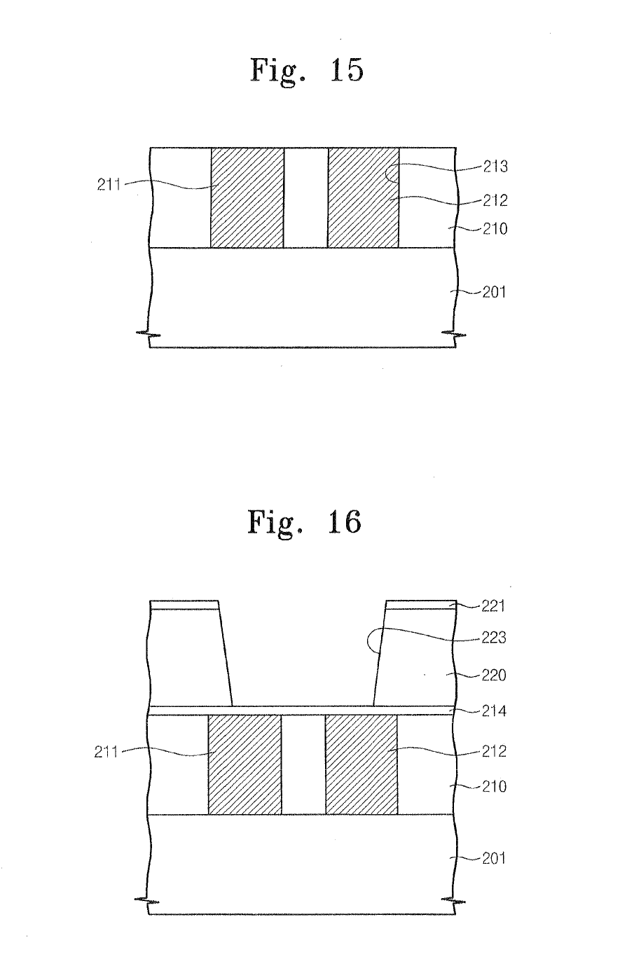

FIGS. 15-20 show a method of forming a cell of a variable resistance memory device according to an exemplary embodiment of the inventive concept.

Referring to FIG. 15, a semiconductor substrate 201 is provided. The semiconductor substrate 201 can be a p-type semiconductor substrate or a p-type semiconductor substrate having an insulating film disposed thereon. A word line WL can be formed in the semiconductor substrate 201 in a first direction. The word line can be formed by doping impurities in the semiconductor substrate 201. A selection device (or circuit) connected to the word line WL can be formed in the semiconductor substrate 201. The selection device includes, for example, a diode, a MOS transistor or a bipolar transistor.

A first interlayer insulating layer 210 is formed on the substrate 201. The first interlayer insulating layer 210 may comprise, for example, silicon dioxide (SiO₂). An opening 213 can be formed through the first interlayer insulating layer 210. A conductive material can be filled in the opening 213. After planarizing the conductive material, a pair of conductive electrode 211, 212 can be formed next to each other in the first interlayer insulating layer 210.

The planarization process can be a CMP process. In an exemplary embodiment, the pair of electrodes 211, 212 can be formed prior to the formation of the first interlayer insulating layer 210. For example, a conductive layer can be formed on the substrate 201. The conductive layer can be patterned to form the pair of electrodes 211, 212. An insulating layer can be formed to cover the pair of electrodes 211, 212. The insulating layer is planarized to expose the pair of electrodes 211, 212 such that the first interlayer insulating layer 210 is formed.

The pair of electrodes 211, 212 can be a heating electrode of the variable resistance memory device. The pair of electrodes 211, 212 can be electrically connected with the selection device (circuit). The pair of electrodes 211, 212 separated from each other can be arranged on the word line WL in the first or second direction.

Referring to FIG. 16, a second interlayer insulating layer 220 is formed on the first interlayer insulating layer 210 and the pair of electrodes 211, 212. The second interlayer insulating layer 220 may comprise, for example, SiO₂. In an exemplary embodiment, a first etch stop layer 214 can be formed on the first interlayer insulating layer 210 prior to forming the second interlayer insulating layer 220. A second etch stop layer 221 can be formed on the second interlayer insulating layer 220. The first and second etch stop layers 214, 221 have a different etch selectivity from other adjacent films or layers. The first and second etch stop layers 214, 221 may comprise, for example, silicon nitride (SiN) or silicon oxynitride (SiON).

A preliminary trench 223 can be formed at the second interlayer insulating layer 220 to expose the first etch stop layer 214. The preliminary trench 223 can overlap the pair of electrodes 211, 212. The preliminary trench 223 can extend in the second direction. In an exemplary embodiment, a width of the upper portion of the preliminary trench 223 is larger than a width of the lower portion of the preliminary trench 223.

Referring to FIG. 17, an outer spacer 232 can be formed on a sidewall of the preliminary trench 223 using an anisotropic etching. Using the outer spacer 232 as an etch mask, the first etch stopper 214 can be etched to expose the pair of electrodes 211, 212.

A trench 226 exposing the pair of electrodes 211, 212 can be formed in the second interlayer insulating layer 220. The trench 226 includes a bottom side 224 exposing the pair of electrodes 211, 212 and a wall side 225 extended from the bottom side 224.

When the outer spacer 232 is omitted, the preliminary trench 223 can also be omitted according to an exemplary embodiment.

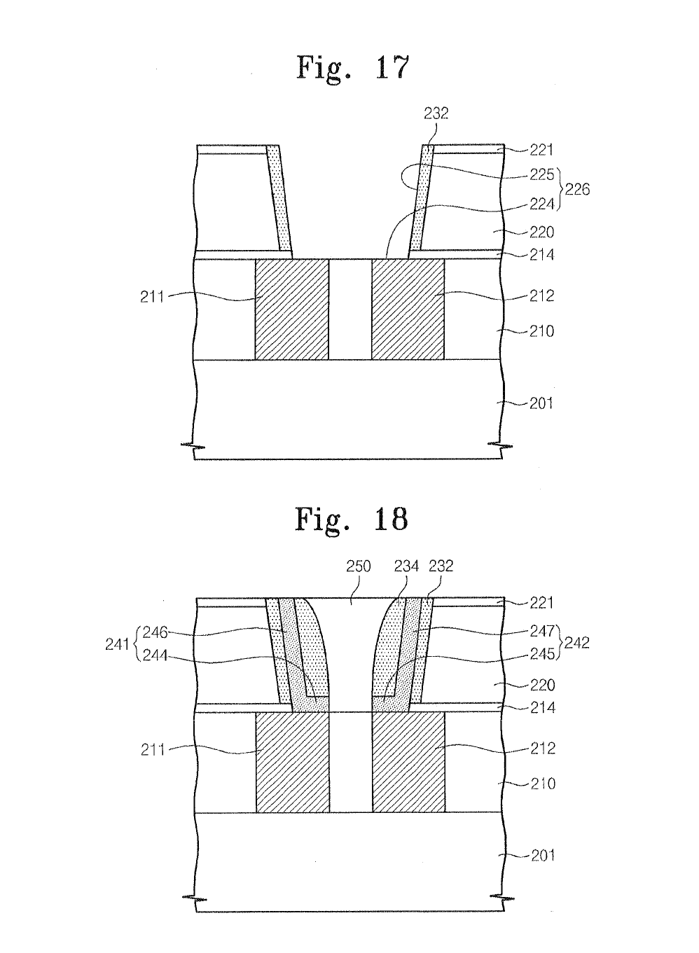

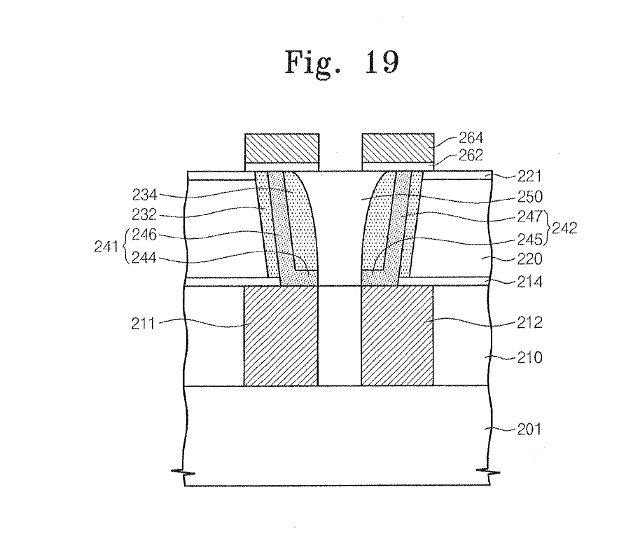

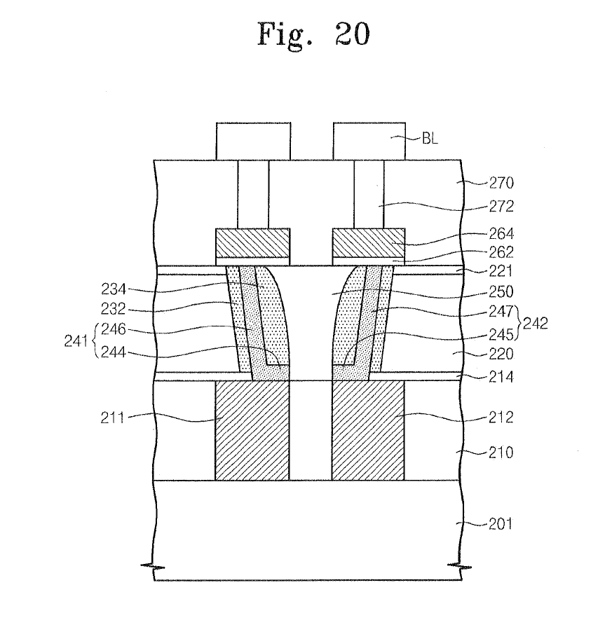

Referring to FIG. 18, a variable resistance material pattern 241, 242 can be formed in the trench 226. An inner spacer 234 can be formed in the trench 226 and cover the variable resistance material pattern 241, 242. Using the inner spacer 234 as a mask, separated variable resistance material patterns 241, 242 can be formed. A gap filling insulating layer 250 can disposed on the inner spacer 234.

Referring to FIG. 19, a second electrode 264 is formed on the second interlayer insulating layer 220. Referring to FIG. 20, a third interlayer insulating layer 270 covering the second electrode 264 can be disposed on the second interlayer insulating layer 220. A contact plug 272 formed through the third interlayer insulting layer 270 can electrically connect the bit line BL, and the second electrode 264.

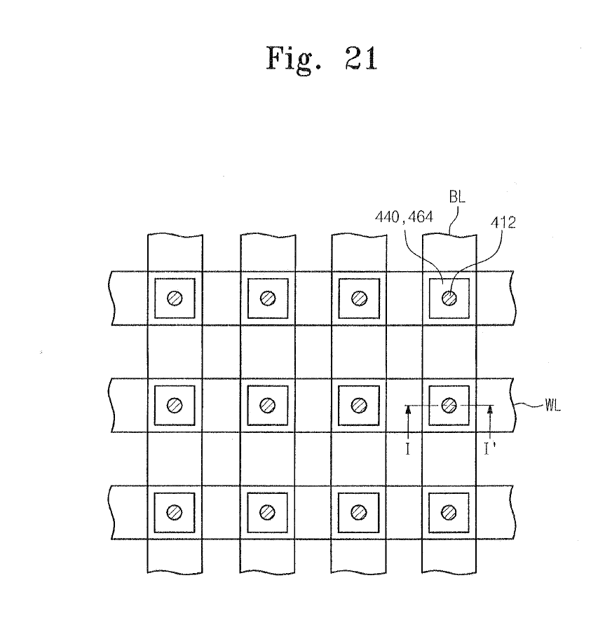

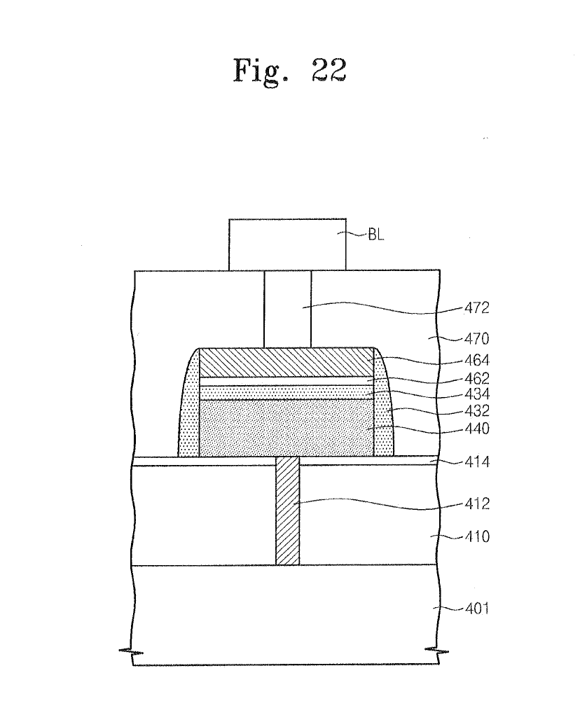

FIG. 21 is a plan view of a variable resistance memory device according to an exemplary embodiment of the inventive concept. FIG. 22 is a cross-sectional view taken along the line I-I′ in FIG. 21 according to an exemplary embodiment of the inventive concept. Referring to FIGS. 21 and 22, a first insulating layer 410 is disposed on substrate 401. A lower electrode 412 is disposed in the first insulating layer 410. The lower electrode 412 is disposed on the substrate 401 at one end and on the variable resistance material pattern 440 at the other end. The variable resistance material pattern 440 is disposed on a first etch stopper 414 and the lower electrode 412. The variable resistance material pattern 440 can have a substantially bar or cubic shape. A top spacer 434 can be disposed on an upper surface of the variable resistance material pattern 440. A side spacer 432 can be disposed on side surfaces of the variable resistance material pattern 440. As such, the variable resistance material pattern 440 can be isolated from the second interlayer insulating layer 470 disposed on the first interlayer insulating layer 410.

A buffer layer 462 can be disposed on the top spacer 434. An upper electrode 464 can be disposed on the buffer layer 462. A bit line BL can be disposed on the second interlayer insulating layer 470. The upper electrode 464 contacts the bit line BL through a metal contact 472 disposed in the second interlayer insulating layer 470.

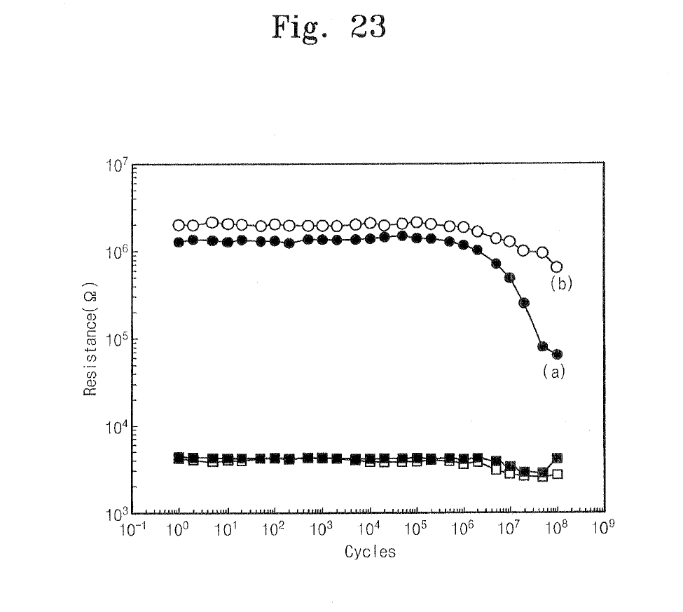

FIG. 23 is a graph showing an endurance of a PRAM when a Ge spacer is used in the device (case b) according to an exemplary embodiment of the inventive concept, and when a Ge spacer is not used in the device (case a). Referring to FIG. 23, the endurance of the PRAM is improved when the Ge spacer is used.

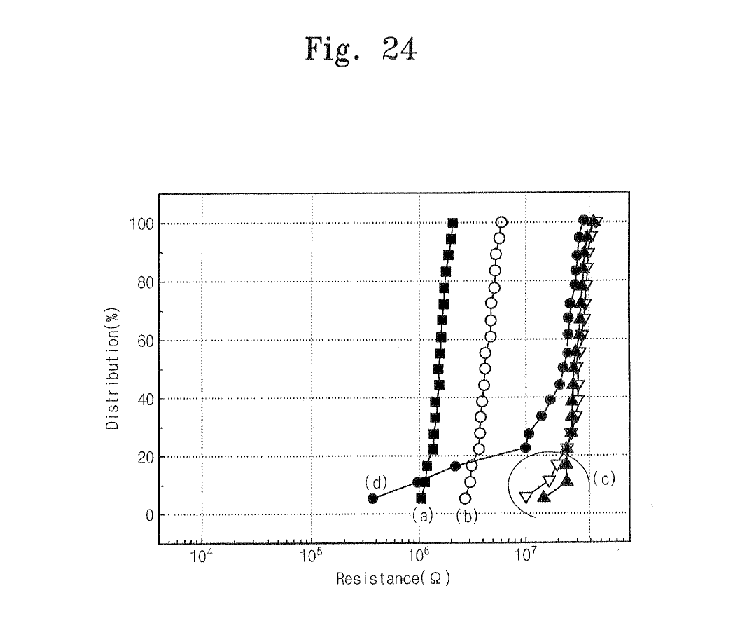

FIG. 24 is a graph showing data retention when a Ge containing spacer is not used in a PRAM. Referring to FIG. 24, (a) indicates a status before data recording, (b) indicates a status before baking after data recording, (c) indicates a status after data recording and baking at 150° C. for about 1 to 2 hours, and (d) indicates a status after data recording and baking at 150° C. for about 4 hours. When a Ge spacer does not cover a Ge—Sb—Te material in a PRAM, a data retention is less than 2 hours during the baking at 150° C.

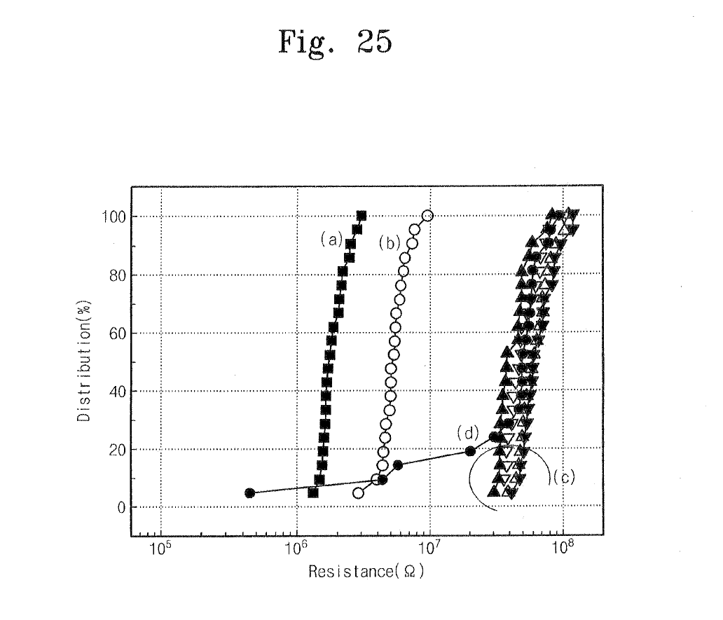

FIG. 25 is a graph showing data retention when a Ge spacer is used in a PRAM according to an exemplary embodiment of the inventive concept. Referring to FIG. 25, (a) indicates a status before data recording, (b) indicates a status before baking after data recording, (c) indicates a status after data recording and baking at 150° C. for about 1 to 12 hours, and (d) indicates a status after data recording and baking at 150° C. for about 24 hours. When a Ge spacer covers a Ge—Sb—Te material in a PRAM, a data retention improves by about 12 hours during the baking at 150° C.

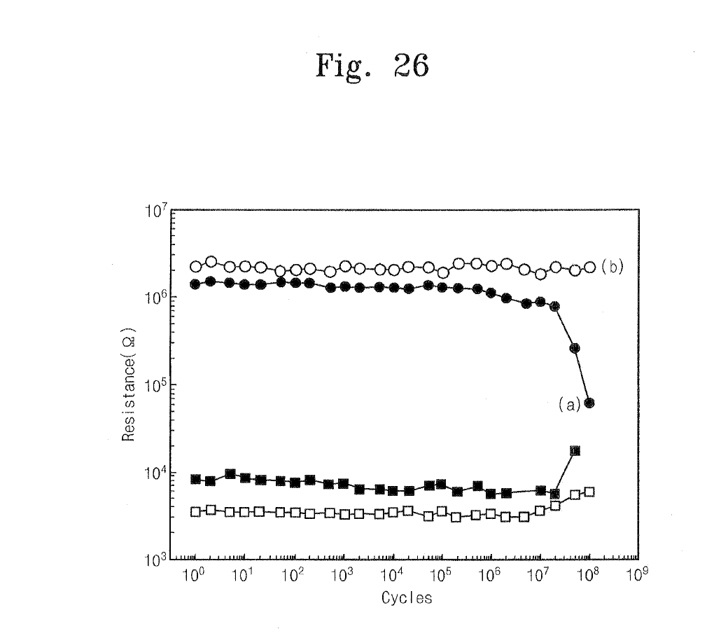

FIG. 26 is a graph showing an endurance of a PRAM when a Ge₁Te₁₋ₓ, spacer is used in the PRAM (case b) according to an exemplary embodiment of the inventive concept, and when a Ge containing spacer is not used in the PRAM (case a). As shown in FIG. 26, an endurance of the PRAM is better when the Ge₁Te₁₋ₓ spacer is used as compared when a Ge spacer is not used.

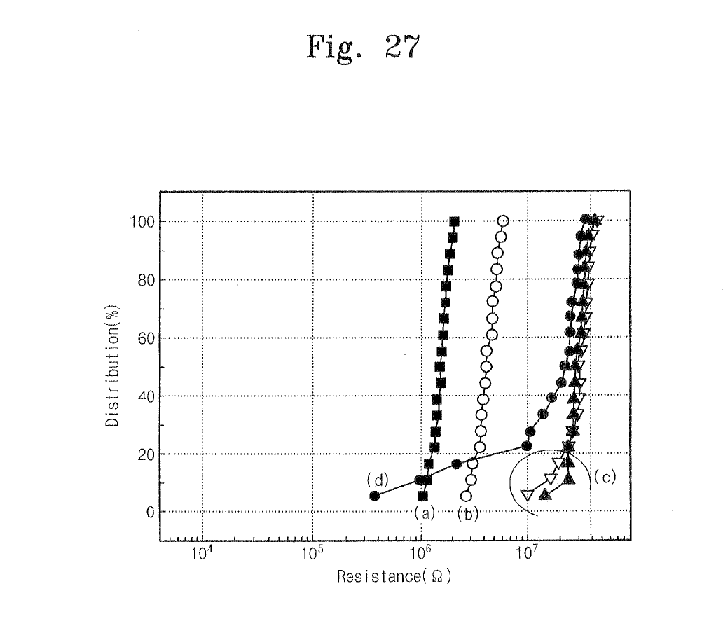

FIG. 27 is a graph showing data retention when a Ge₁Te₁₋ₓ spacer is not used in a PRAM. Referring to FIG. 27, (a) indicates a status before data recording, (b) indicates a status before baking after data recording, (c) indicates a status after data recording and baking at 150° C. for about 1 to 2 hours, and (d) indicates a status after data recording and baking at 150° C. for about 4 hours. When a Ge₁Te₁₋ₓ spacer does not cover a Ge—Sb—Te material in a PRAM, a data retention is less than 2 hours during the baking at 150° C.

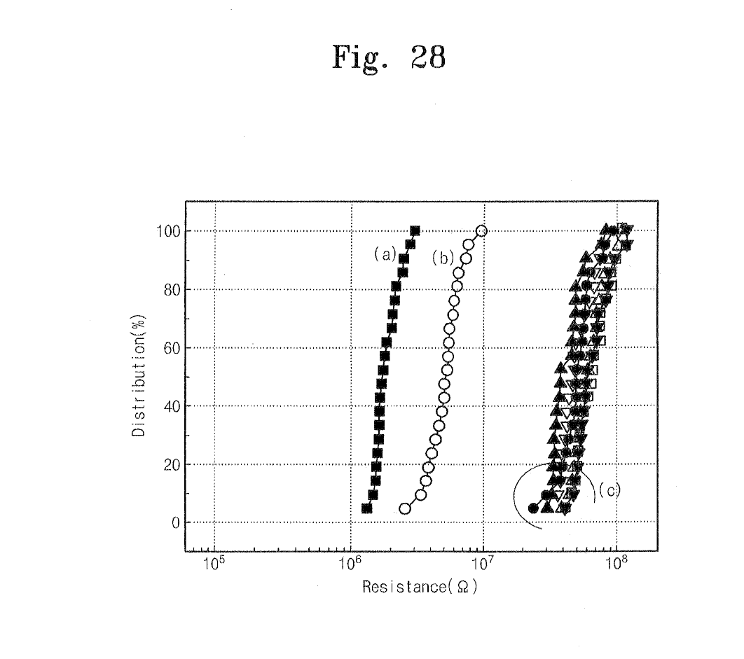

FIG. 28 is a graph showing data retention when a Ge₁Te₁₋ₓ spacer is used in a PRAM according to an exemplary embodiment of the inventive concept. Referring to FIG. 28, (a) indicates a status before data recording, (b) indicates a status before baking after data recording, and (c) indicates a status after data recording and baking at 150° C. for about 24 hours. When a Ge spacer covers a Ge—Sb—Te material in a PRAM, a data retention improves by about 24 hours during the baking at 150° C.

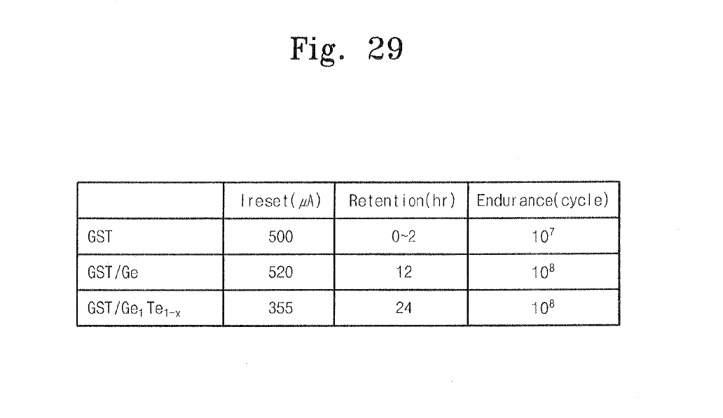

FIG. 29 is a table showing reset current, retention time, and endurance of a PRAM according to an exemplary embodiment of the inventive concept as compared to a PRAM that does not have a Ge or Ge₁Te₁₋ₓ spacer on the variable resistance material pattern.

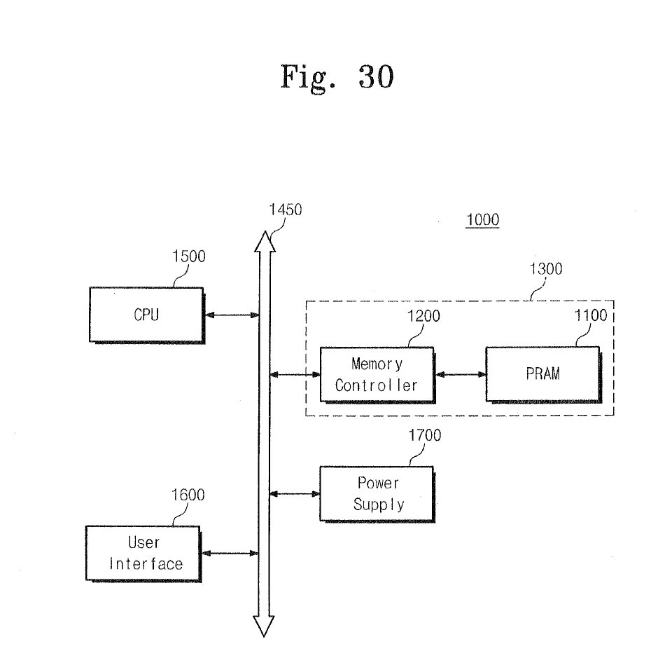

FIG. 30 is a block diagram of a memory system in which a variable resistance memory device according to an exemplary embodiment of the inventive concept may be implemented.

Referring to FIG. 30, a memory system 1000 includes a semiconductor memory device 1300 including a variable resistance memory device, e.g., a PRAM 1100, and a memory controller 1200. The system 1000 further includes a central processing unit (CPU) 1500, a user interface 1600 and a power supply 1700. The components of the system 1000 may be communicatively coupled to each other through a data bus 1450.

Data provided through the user interface 1600 or generated by the central processing unit (CPU) 1500 is stored in the variable resistance memory device 1100 through the memory controller 1200. The variable resistance memory device 1100 may include a solid state drive. Although not shown, an application chipset, a camera image processor (CIS), and a mobile DRAM may be further provided to the memory system 1000 in an exemplary embodiment of the inventive concept. The memory system 1000 can be applied to a personal digital assistant (PDA), a portable computer, a web tablet, a wireless phone, a mobile phone, a digital music player, a memory card or devices which can transmit and/or receive data in a wireless environment.

The variable resistance memory device or the memory system according to an exemplary embodiment of the inventive concept may be mounted in a variety of packages. For example, the variable memory device or the memory system may be packaged in a package on package (PoP), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline integrated circuit (SOIC), shrink small outline package (SSQP), thin small outline package (TSOP), system in package (SIP), multi chip package (MCP), wafer-level fabricated package (WFP), or wafer-level processed stack package (WSP).

Although the exemplary embodiments of the present invention have been described herein with reference to the accompanying drawings, it is to be understood that the present invention should not be limited to those precise embodiments and that various other changes and modifications may be affected therein by one of ordinary skill in the related art without departing from the scope or spirit of the invention. All such changes and modifications are intended to be included within the scope of the invention as defined by the appended claims.

What is claimed is:

1. A semiconductor memory device comprising:
a first electrode and a second electrode;
a variable resistance material pattern comprising a first element disposed between the first and second electrode; and
a first spacer comprising the first element, the first spacer disposed adjacent to the variable resistance material pattern.

2. The device of claim 1, wherein the first element comprises Ge.

3. The device of claim 1, wherein the variable resistance material pattern comprises a phase change material.

4. The device of claim 1, wherein the first spacer comprises DₐM_{b}Ge, where 0≦a≦0.7, 0≦b≦0.2, D comprises C, N or O, and M comprises Al, Ga, In, Ti, Cr, Mn, Fe, Co, Ni, Zr, Mo, Ru, Pd, Hf, Ta, Ir or Pt.

5. The device of claim 1, wherein the variable resistance material pattern comprises at least one of DGeSbTe where D comprises C, N, Si, Bi, In, As or Se, DGeBiTe where D comprises C, N, Si, In, As or Se, DSbTe where D comprises As, Sn, SnIn, W, Mo or Cr, DSbSe where D comprises N, P, As, Sb, Bi, O, S, Te or Po, or DSb where D comprises Ge, Ga, In, Ge, Ga or In.
